(19) United States
(12) Patent Application Publication
(10) Pub. No.: US 2005/0040034 A1
(43) Pub. Date: Feb. 24, 2005

(54) Coating method and coating

(76) Inventors: Ralf Landgraf, Deggendorf (DE); Michael Schmitt, Zwiesel (DE); Jorg Moennekes, Hoexter (DE); Karl Haeuser, Beverungen (DE); Rolf Blessing, Trendelburg (DE); Davorin Pavic, Goettingen (DE); Lothar Herlitze, Derental (DE); Wilhelm Herwig, Beverungen (DE); Reimund Boewer, Beverungen (DE)

Correspondence Address: Leopold Presser;Scully Scott Murphy & Presser, 400 Garden City Plaza, Garden City, NY, 11530, US

(21) Appl. No.: 10/497,867

(22) PCT Filed: Dec. 4, 2002
(86) PCT No.: PCT/EP02/13743

(30) Foreign Application Priority Data
Dec. 6, 2001 (DE) 101 59 907.2

(51) Int. Cl. C23C 16/00

(52) U.S. Cl. 204/192.38; 427/580; 427/569; 427/248.1

(57) ABSTRACT

The invention relates to a method for applying one or several coats to a substrate in a device comprising a PVD/CVD coating chamber. One solid matter is physically transformed at least in part into a gaseous phase and is applied to the substrate in the gaseous phase. At least one additional compound and/or one additional metal is added to the gaseous phase in liquid or gaseous form, and the at least one additional compound and/or the at least one additional metal reacts with the surface of the substrate. The invention also relates to a coating that is produced according to said method.

The invention relates to a method for applying one or several coats to a substrate in a device comprising a PVD coating chamber. One solid matter is physically transformed at least in part into the gaseous phase and is applied to the substrate in the gaseous phase, as well as coatings produced in accordance with the method.

Various coating processes are known in prior art (for example from Kienel, Röll, “Vacuum coating 2”, VDI Publishers, 1995, ISBN 3-18-401312-X, Chap. 5 and Chap. 10).

Metal or metal oxide coatings can be applied to a substrate by means of the so-called PVD methods (PVD: physical vapour deposition). PVD methods are understood to comprise vacuum coating processes for the production of thin coats on substrates, in which the coating material is transformed by purely physical methods into the gaseous phase, in order to be then deposited on the substrates.

In a development of this method, the coating material is heated up in high vacuum until it is transformed into the gaseous state. Heating up can take place by means of electrical resistance heating, by bombardment with high-energy electrons or by laser beam bombardment. The vaporized coating material is then deposited on a substrate.

Also the sputter process, which is also called cathodic arc evaporation, ranks among the PVD methods. Here, a plasma is ignited by a direct or high frequency voltage between two electrodes in a vacuum chamber at constant gas pressure, 1 Pa for example. Positive gas ions, for example argon ions, arising in the plasma, are accelerated and collide with a solid matter, which is also called target, arranged on the cathode. The atoms driven out of the solid matter by the colliding argon ions diffuse through the plasma and are deposited on the substrate arranged on the anode.

With the known methods it is disadvantageous that the coating rates are frequently too low. In particular, when coating wide substrates such as window glass, which is manufactured in large quantities, it is desirable for economic reasons to increase the unit volume of coated glass surface area per unit of time.

In addition the so-called CVD method (CVD: chemical vapour deposition) is frequently used for coating substrates. With this method a gas which contains a reactant is supplied to a substrate in a reactor. The reactant reacts, while forming a reaction product, when energy is supplied to the substrate surface. For example, metal oxide or metal nitride coatings can be applied using the CVD method.

Object of the present invention therefore is to provide a method for coating substrates, which permits substrates to be coated efficiently and homogeneously as well as to provide a corresponding coating.

The object underlying the invention is achieved by a method according to claim 1. Preferred refinements are indicated in the sub-claims. Furthermore, the object is also achieved by a coating produced according to the method in accordance with the invention according to claim 14.

The method in accordance with the invention can be carried out in a modified PVD coating chamber. The substrate, for example float glass, is placed in the coating chamber and a suitable negative pressure is applied. The negative pressure, for example, ranges from 0.1 to 10 Pa, preferably from 1 to 5 Pa.

The solid matter (and/or the target) is vaporized by a suitable method. The vaporization and/or transformation of the solid matter into the gaseous phase can be caused preferably by heating, for example inductive heating, cathodic arc evaporation, magnetron sputtering, electron-, ion- and/or laser beam bombardment (laser ablation) and combinations of these.

In accordance with a preferred embodiment, the solid matter is transformed into the gaseous phase by means of cathodic arc evaporation and/or sputtering process, whereby a plasma is formed between cathode and anode.

The at least one additional compound and/or the at least one additional metal can be added in gaseous form through at least one inlet of the PVD/CVD coating chamber. The aforementioned compounds and/or metals can however be added in liquid form, for example as aerosol, by means of a carrier gas, to the coating chamber. Preferably, the aforementioned compounds and/or metals are added in gaseous form.

The inlets are arranged in this case according to the geometry of the coating chamber on or in the coating chamber in such a way that the at least one additional compound and/or at least one additional metal is uniformly spread over the entire substrate surface. In this way, a fast transfer to the entire substrate surface, while forming a homogeneous coating, is caused.

With a very much preferred embodiment of the invention the at least one additional compound and/or the at least one additional metal is contained in the sputter gas. An inert gas, for example a noble gas, preferably argon, is used as sputter gas for example. The at least one additional compound and/or the at least one additional metal preferably in gaseous form is blended with the sputter gas, for example in a mixing chamber. The gaseous mixture produced in this way can then be brought into the PVD coating chamber in a conventional manner.

The method in accordance with the invention thus represents a combination of the PVD and CVD methods.

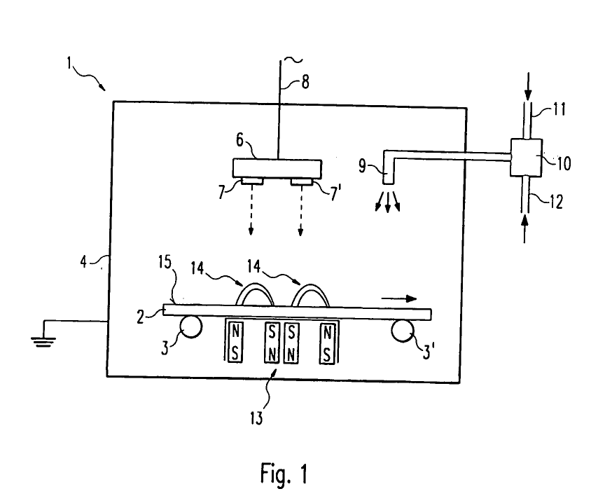

FIG. 1 as an example shows a coating chamber 1 for such a method in accordance with the invention. A substrate 2 is coated in the coating chamber 1, whereby the substrate 2 is transported on rollers 3, 3′ in the direction indicated by the arrow. The coating chamber 1 is spatially limited by a surrounding wall 4, which lies on a ground potential 5.

A cathode 6, on which in the embodiment illustrated two targets 7 and 7′ are arranged, is provided in the coating chamber 1. The cathode 6 can be supplied, for example, with an AC voltage and for this purpose is connected by means of an electric supply lead 8 to a generator. The material is applied on the surface 15 of the substrate 2 by sputtering the coating material from the target 7 as well as the target 7′. The sputtered material then evaporates on the surface 15 of the substrate 2.

In order to sputter material from the target 7 and the target 7′, a plasma is ignited in the coating chamber 1. For igniting the plasma a sputter gas, which is introduced into the coating chamber 1 through a gas supply orifice 9, is present in the coating chamber 1.

Via the gas supply orifice 9 it is also possible, in addition to the sputter gas to introduce one additional compound or one additional metal into the coating chamber 1, by feeding the additional compound or the additional metal into a mixing chamber 10. A first feed line 11 as well as a second feed line 12, through which the sputter gas as well as the additional compound and/or the additional metal are supplied to the mixing chamber 10 are connected to the mixing chamber 10. The mixture of the sputter gas and the additional compound, which is a coating gas, or a vaporized metal, is then introduced together through the gas supply orifice 9 into the coating chamber 1.

In order to increase the coating rate, a magnetron 13 is arranged on the side of the substrate 2 turned away from the cathode 6. The magnetron 13 generates a magnetic field 14, which acts on the top directly above the surface 15 of the substrate 2. The magnetic field 14 causes an increase in the plasma density over the surface 15 of the substrate 2. In this case, it has been shown that the increased plasma density over the substrate 2 leads to an improvement of the coating rate while applying a homogeneous coating on the surface 15 of the substrate 2.

The additional compound, which is mixed with the sputter gas via the mixing chamber 10, is itself already a film-forming gas. In place of such a gaseous additional compound an aerosol, which is mixed with the sputter gas in the mixing chamber 10 and likewise introduced through the gas supply orifice 9 into the coating chamber 1, can also be supplied to the mixing chamber 10.

Alternatively to the embodiment illustrated, in which the additional compound and/or the additional metal is mixed with the sputter gas outside the coating chamber 1 in the mixing chamber 10, the mixture can also be blended within the coating chamber 1. At the same time, a mixing chamber 10 can also be completely dispensed with. The individual components are then introduced directly into the coating chamber 1 through separate gas supply orifices and are then mixed directly in the coating chamber 1.

Likewise, the illustration of a cathode 6, on which two targets 7 and 7′ are arranged as planar targets is only by way of example. It is also conceivable to use hollow cathodes of the other systems for carrying out a PVD process.

Totally surprisingly, it has been shown that the method in accordance with the invention in particular permits an extremely homogeneous coating to be applied to wide substrates, as for example window glass, in a shorter time compared with conventional methods.

The plasma is ignited in the case of the method in accordance with the invention in the coating chamber at constant gas pressure by a direct or high frequency voltage between cathode and anode. In accordance with one preferred refinement several cathodes, for example two cathodes, which can be formed as double cathodes, are used. The gas pressure can range from 0.1 to 10 Pa, preferably from 1 to 5 Pa. A voltage of approximately 600V as well as a frequency ranging from 1 to 500 kHz is preferably used for the high frequency voltage.

The plasma-supported coating can also take place by way of pulse operation. For example, with the method in accordance with the invention the plasma can be pulsed as in the case of the plasma pulse PVD method.

With the plasma pulse PVD method normally under continuous flow of the coating gases the electrical supply line energizing the plasma is pulsed, whereby a thin coating forms on the substrate with every pulse.

Because a pulse pause follows each voltage pulse, in an extremely advantageous way high voltages can be applied during a pulse even to substrates which are not temperature-stable. For example, the plasma pulse PVD method for example permits coatings to be applied to substrates made of polymer materials, for example polymethyl methacrylate, which are temperature-sensitive.

In accordance with one preferred embodiment, the plasma is formed in a double ion source.

The ions may be ions of the filling gas or even ions of the coating material. In this case the pressure can range from 0.1 to 10 Pa, preferably from 1 to 5 Pa. The high-energy ions of the double ion source preferably possess an energy of approximately 100 eV up to several KeV.

In accordance with a further very much preferred embodiment, the plasma is formed by means of a reverse magnetron. It is understood under a reverse magnetron within the sense of the invention that a magnetic field is generated by a magnetron, which is arranged on the side of the substrate turned away from the surface to be coated and not, as is usual with the cathodic arc evaporation method, on the cathode side behind the target material. As the result of a magnetron arranged in such a way behind the substrate a magnetic field is also generated on that side of the substrate, towards which the surface to be coated is directed. Thus an increased plasma density is also formed directly above the substrate, which leads to a higher coating rate.

With this method, the coating depends exclusively on the type of the filling gas. If an inert gas, for example argon, is supplied to the coating chamber, plasma etching of the substrate takes place. If a dissociable gas or gas-aerosol mixture, for example metal-organic compounds, is supplied, a coating is deposited on the substrate. The pressure in this case can range from 0.1 to 10 Pa, preferably from 1 to 5 Pa.

In accordance with a further preferred embodiment, the cathodic arc evaporation method is combined with the CVD method. One cathode is preferably used and/or several cathodes are preferably used as a sputter cathode, for example a double cathode or several double cathodes, which have a length of several metres, for example from 1 to 4 metres. The use of sputter cathodes with the aforementioned dimensions makes it possible to produce a homogeneous plasma over the entire coating width of in particular wide substrates, for example window glass. In this homogeneous plasma, the substrates are coated at high speed.

In accordance with one preferred refinement of the invention, the cathodes are supplied with alternate frequency, for example from 1 to 500 kHz, preferably from 10 to 100 kHz, in order to ensure the elimination of charged particles. For example, a medium frequency process operating in bipolar fashion guarantees an essentially coating-free cathode for eliminating charged particles and thus a temporally stable coating process.

A medium frequency method operating in bipolar fashion is understood within the sense of the invention to be a double cathode arrangement, so that the two cathodes located in the recipient are supplied with high frequency voltage. The ions in a half wave in each case undergo acceleration towards the corresponding cathode, on which the sputtering of the target takes place. This method permits coatings, in particular consisting of non-conductive material, to be produced. In this case preferably a voltage of approximately 600V as well as a frequency ranging from 1 to 500 kHz are used for the high frequency voltage.

In accordance with one preferred embodiment of the invention conventional double cathodes without magnetic field, magnetron double cathodes, double hollow cathodes, double ion sources as well as combinations of these are used as cathodes.

As cathodes the use of double hollow cathodes is extremely preferred, because high-insulation coatings can be deposited as the result of the permanent supply to an exposed target area.

With the method in accordance with the invention, in an extremely advantageous way one or several thin coats can be applied in particular on wide substrates. It has been shown that the applied coats are very homogeneous.

It is understood under a homogeneous coating within the sense of the invention that when coating large surfaces, for example up to 4 metres wide and in the complete coating cycle approximately 1000 metres long, uniform coating thickness and thus colour consistency is reached over the entire width of the substrate. The fluctuation in coating thickness in this case amounts to less than 1%.

The applied thin coats can be coatings consisting of metal, metal oxide and/or metal nitrides, semiconductors, semiconductor oxides and/or semiconductor nitrides.

For example, defined coating systems consisting of silicon oxide, silicon nitride, titanium oxide, and/or titanium nitride, as well as other coatings can be applied on a substrate.

The following main and secondary groups in the element classification system are preferably used as gaseous and/or liquid compounds and/or colloid-disperse solutions of metal and/or metal compounds: sub-groups IVb, in particular titanium, zirconium and hafnium; Vb, in particular vanadium, niobium and tantalum; VIb, in particular chrome, molybdenum and tungsten; VIIb, in particular iron, cobalt, nickel, palladium and platinum; Ib, in particular copper, silver and gold; IIb, in particular zinc and cadmium as well as the main groups III, in particular aluminium, gallium and indium; IV, in particular carbon, silicon, germanium, tin and lead; V, in particular arsenic, antimony and bismuth, as well as VI, in particular selenium and tellurium.

Gaseous or soluble metal and/or metal-organic compounds are particularly preferred such as for example: TiCl₄, GeH₄, Ti[OC₃H_{7]4}, Al[OC₂H₅]₃, Al[OC₃H₇]₃, Al[C₅H₇O₂]₃, Ga[C₅H₇O₂]₃, In[C₅H₇O₂]₃, Zn [CH₃]₂, Zn[CH₃H₅O₂]₂, Sn[CH₃]₄, TA[OC₄H₉]₅, Zr[OC₄H₉]₄, Hf[OC₄H₉]₄ or mixtures of these.

For applying coats from silicon oxide or silicon nitride in particular colloid-disperse solutions and/or soluble organosilanes are suitable, for example SiO₂, SiH₄, Si₂H₆, Si[OC₂H₅]₄ (TEOS), Si[OCH₃]₄, (TMOS), [Si(CH₃)₃]₂ (HMDS), Si[CH₃]₃]₂O, (HMDSO), Si[CH₃]₄ (TMS), [SiO(CH₃)₂]₄, [SiH(CH₃)₂]₂O or mixtures of these.

The aforementioned colloid-disperse solutions are dissolved in solvents suitable for CVD methods, for example methanol, ethanol, propanol, acetone, ether, amides, esters or amines.

Before adding the liquid compounds and/or colloid-disperse solutions of the metal compounds or metals into the PVD/CVD coating chamber, these can be supplied for example to an atomizer device or a vaporizer/carburetor for liquids. In this gasification device, various compounds can be mixed with one another in certain ratios while supplying a carrier gas, in order then to transform the compound and/or the compound mixture into the gaseous form. The gas produced in this way can then be added to the PVD/CVD coating chamber accordingly.

With the method in accordance with the invention, one or several coats, arranged one above the other, can be applied to a substrate with exactly defined thickness, structure, refractive index and/or composition.

For example, the following defined coats can be produced by means of the method in accordance with the invention (n: refractive index):

| | |
|---|---|
| a.) Titanium oxide/TiN: | 2.1 ≦ n ≦ 2.7 |
| b.) SiOₓ/SiₓN_{y}: | 1.3 ≦ n ≦ 1.9 |
| c.) Tin oxide/tin nitride: | 1.8 ≦ n ≦ 2.1 |
| d.) Zinc oxide/zinc nitride: | 1.8 ≦ n ≦ 2.2 |

In the case of the exemplary coatings indicated above a.) to d.), which can be produced according to the method in accordance with the invention, hydrophobic coatings can be produced within the range of the low refractive indices in each case.

The hydrophobic surfaces have outstanding dirt repellent properties and are therefore very easy to clean and/or are self-cleaning.

1. Method for applying one or several coats to a substrate in a device comprising a PVD/CVD coating chamber, one solid matter being physically transformed at least in part into the gaseous phase by cathodic arc evaporation, using a sputter gas and applied to the substrate in the gaseous phase, whereby at least one additional compound and/or one additional metal in liquid or gaseous form is added to the gaseous phase and the at least one additional compound and/or the at least one additional metal reacts at least in part with the surface of the substrate, whereby in the coating chamber the solid matter is arranged on the cathode and the substrate is arranged on the anode and a plasma is formed between cathode and anode,
characterised in that the plasma is formed using a magnetron, the magnetron being arranged on a side turned away from the surface of the substrate to be coated, whereby an increased plasma density is produced by the magnetron directly above the surface of the substrate to be coated.

2. Method according to claim 1, characterised in that the transformation of the solid matter into the gaseous phase is caused by a combination of heating, magnetron sputtering, electron-, ion- and/or laser beam bombardment (laser ablation) with the cathodic arc evaporation.

3. Method according to claim 1 or 2, characterised in that at least two cathodes are arranged in the coating chamber.

4. Method according to any one of claims 1 to 3, characterised in that one or several cathodes are supplied with alternate frequency.

5. Method according to claim 3 or 4, characterised in that the at least two cathodes are formed as rotary cathodes, double cathodes without magnetic field, magnetron cathodes, magnetron double cathodes, double hollow cathodes with or without magnetic field and combinations of these.

6. Method according to any one of claims 1 to 5, characterised in that the at least one additional compound and/or one additional metal is contained in the sputter gas.

7. Method according to any one of claims 1 to 6, characterised in that the compounds are selected from the group of compounds for production of thin coats consisting of single or multi component oxides, in particular silicon oxide, titanium oxides, chromium oxide, aluminium oxide, tungsten oxides, tantalum oxides, or of mixed metal oxide/metal nitride, in particular silicon-oxide silicon nitride, titanium oxide-titanium nitride, of metal nitrides, in particular silicon nitride, titanium nitride.

8. Method according to any one of claims 1 to 7, characterised in that the compounds are selected from the group of gaseous or soluble and metal or metal-oxide compounds.

9. Method according to any one of claims 1 to 6, characterised in that the compounds are selected from the group of soluble or gaseous metal-organic compounds, preferably organosiloxanes.

10. Coating, characterised in that the coating is produced by a method according to any one of claims 1 to 9.

11. Coating according to claim 10, characterised in that the coating has a hydrophobic surface.
